(19) United States
(12) Patent Application Publication
(10) Pub. No.: US 2022/0077557 A1
(43) Pub. Date: Mar. 10, 2022

(54) Power Divider

(71) Applicant: Ampleon Netherlands B.V., Nijmegen (NL)

(72) Inventor: Mohadig Widha Rousstia, Nijmegen (NL)

(21) Appl. No.: 17/413,483

(22) PCT Filed: Dec. 12, 2019
(86) PCT No.: PCT/NL2019/050832

§ 371 Date: Jun. 11, 2021

(30) Foreign Application Priority Data
Dec. 12, 2018 (NL) 2022186

(51) Int. Cl. H01P 5/08; H01P 5/02; H05K 1/02

(52) U.S. Cl. CPC H01P 5/08; H01P 5/028; H05K 2201/09636; H05K 1/0251; H05K 1/024

(57) ABSTRACT

Example embodiments relate to power dividers. One example power divider includes a dielectric unit that includes one or more dielectric layers and has a first surface and a second surface. The power divider also includes a first transmission line unit being of a coplanar type or a stripline type. The first transmission line unit includes a plurality of first transmission lines, each first transmission line including a respective first line segment and a respective second line segment. The first transmission line unit also includes a first dielectric layer. The power divider also includes a second transmission line unit. The second transmission line unit includes a second transmission line. The second transmission line unit also includes a second dielectric layer. Further, the power divider includes a first via. In addition, the power divider includes a plurality of second vias distributed around the first via.

The present invention relates to a power divider. The invention further relates to an antenna unit comprising such a power divider and to an electronic device comprising the same. In the field of RF electronics, power combining and power splitting techniques are well known. The objective of power combining and splitting is generally to uniformly distribute or gather RF signals. It should be noted that the wording power divider and power combiner are used interchangeably throughout this text unless stated otherwise. For example, by reversing the flow of signals, most power dividers can be used as power combiners.

The present invention particularly relates to reciprocal splitters. These splitters are typically passive and are manufactured using isotropic materials.

An example of a power divider, corresponding to the preamble of claim 1, is known from the paper “A Wideband Radial Substrate Integrated Power Divider at K-Band”, by Christian Rave et al, GeMiC 2015, Mar. 16-18, 2015, Nürnberg, Germany.

In this paper, a power divider is presented that comprises a three layer dielectric substrate. On the top layer, line segments are arranged that form transmission lines together with associated ground planes that are arranged in between the top layer and the intermediate layer. These line segments extend radially from a common region. On the bottom layer, a line segment is arranged that forms a transmission line together with an associated ground plane that is arranged in between the bottom layer and the intermediate layer.

A plurality of vias extend through the entire substrate and electrically connect the associated ground plane located in between the intermediate layer and the bottom layer and the associated ground planes that are located in between the intermediate layer and the top layer. Together, these vias form an electrical fence.

A central via connects the line segment on the bottom layer to the common region on the top layer. Located in between the central via and the via fence, further vias are provided that extend downward from the line segments on the top layer.

In the power combiner described in this paper, a cavity is formed in the intermediate layer. Electromagnetic waves are excited in this cavity by the via that extends upward from the line segment on the bottom layer. These waves are picked up by the further vias in such a manner that power supplied to the line segment on the bottom layer is equally distributed over the line segments on the top layer. The electromagnetic energy is kept within the cavity using the abovementioned electrical fence.

A drawback of this known power combiner is related to the size of the cavity. This cavity extends in a lateral direction, i.e. parallel to the dielectric layers, and is bounded by the via fence. As such, the lateral area that is occupied by the power combiner substantially corresponds to the outer dimensions of the via fence. The region occupied by the cavity cannot be used for other purposes, such as signal routing.

It is an object of the present invention to provide a solution to this problem.

This object has been achieved by the power divider as defined in claim 1 that is characterized in that the first via is electrically isolated from the first associated ground planes and the second associated ground plane, and in that the first via and the plurality of second vias act as a coaxial transmission line having an inner conductor formed by the first via and an outer conductor formed by the plurality of second vias.

According to the invention, the first via and the plurality of second vias act as a coaxial transmission line. This line supports a transverse electromagnetic (TEM) wave. This wave is uniform in the circumferential direction. At the end of the coaxial transmission line, where it is connected to the common region, the wave is split over the plurality of first transmission lines of which the first line segments all extend from the common region. As a result of the uniform character of the TEM wave in the circumferential direction, a highly uniform distribution of the TEM wave over the plurality of first transmission lines can be achieved. In addition, contrary to the known power combiner of Rave et al, the second line segment is not connected to ground but has a direct connection to the first line segments, thereby also allowing DC signals to be divided.

It should be noted that throughout this text, multilayer dielectric substrates are discussed in which metal layers are arranged on various dielectric layers. In some cases, the metal layer can be arranged between directly adjacent dielectric layers, e.g. layer A having a first surface that contacts a second surface of layer B. In such case, the wording “metal layer arranged on the first surface of layer A”, “metal layer arranged on the second surface of layer B”, and “metal layer arranged in between layer A and layer B” is considered equivalent.

In addition, the plurality of first associated ground planes can be merged into one or more larger first associated ground planes. Still, even if a single ground plane is used, regions of such plane can be identified as the respective first associated ground planes.

Furthermore, a case in which a metal layer is embedded in a single dielectric layer is considered equivalent to the case in which this same metal layer is arranged between two dielectric layer that together form said single dielectric layer.

The power divider of the present invention is preferably configured to convert a second electromagnetic wave of a second type that is supported by the second transmission line into a TEM wave that is supported by the plurality of second vias and the first via that act as a coaxial transmission line. For example, the second transmission line could be a microstrip, a stripline, or a coplanar waveguide, each supporting a quasi-TEM electromagnetic wave.

Furthermore, the power divider is preferably configured to convert said TEM wave into a first electromagnetic wave of a first type that is supported by the first transmission lines. For example, the first transmission lines could each be, separately and independently, a microstrip, a stripline, or a coplanar waveguide, each supporting a quasi-TEM electromagnetic wave. It is noted that the second transmission line, and the plurality of first transmission lines could each be a transmission line of a different type.

The second vias can be distributed uniformly and annularly around the first via. For example, a distance between a central point of the first via and a central point of a second via could be identical for each second via. Furthermore, a central point of the first via could be identical to a central point of the common region.

Each of the second vias and the first via may comprise a hole extending through at least said one or more dielectric layers of the dielectric unit between a first end and a second end. The hole may comprise an inner wall that is covered with metal. A first metal pad may be formed at the first end, and a second metal pad may be formed at the second end. The first and second metal pads may be electrically connected through the metal covering of the inner wall.

The second vias can be arranged such that the first and/or second metal pads of adjacent second vias touch each other thereby enabling electrical contact. Such contact can also be ensured if the power divider further comprises a first annular metal ring that mutually connects the first metal pads and/or a second annular metal ring that mutually connects the second metal pads. Shapes and/or forms other than an annular ring for the purpose of electrically connecting the second vias are not excluded.

The common region may comprise a patch, preferably a circular patch, and preferably corresponding to the first or second metal pad as defined above.

An operational frequency of the power divider may lie in a range between 1 GHz and 100 GHz. A thickness of the dielectric unit may be larger than 0.05 times an electrical wavelength of a TEM wave propagating through the dielectric unit at the operational frequency. By having a minimum thickness, it can be ensured that fringing fields associated with the conversion of electromagnetic waves at the first and second ends of the first via do not interfere with each other. In other words, by having this minimal thickness, it can be ensured that only a TEM wave propagates through at least a part of the dielectric unit.

The first transmission line unit may comprise a first dielectric layer having a first surface directed away from the dielectric unit and a second surface contacting the dielectric unit. The first line segments and the common region can be arranged on one of the first and second surface and wherein the first associated ground planes are arranged on the other of the first and second surface.

As a first example, the first line segments and the common region can be arranged on the first surface of the first dielectric layer. In this case, the first via extends through the first dielectric layer. This configuration corresponds to a microstrip line. In a further example, the power divider may comprise a further first dielectric layer, wherein the first dielectric layer is arranged in between the further first dielectric layer and the dielectric unit, wherein the further first dielectric layer comprises a first surface directed away from the first dielectric layer and a second surface contacting the first dielectric layer. Each first transmission line may further comprise a respective further first associated ground plane that is arranged on the first surface of the further first dielectric layer. In addition, the plurality of second vias extend through the first dielectric layer and the further first dielectric layer. This configuration corresponds to a stripline.

In a second example, the first line segments and the common region are arranged on the second surface of the first dielectric layer, and the plurality of second vias extend through the first dielectric layer. This configuration corresponds to a reversed microstrip in which the first associated ground planes are arranged on the first surface of the first dielectric layer.

In a third example, the first line segments, the common region, and the first associated ground planes are arranged on the first surface of the first dielectric layer. In this example, the first via and the plurality of second vias extend through the first dielectric layer. This configuration corresponds to a coplanar waveguide.

In a fourth example, the first line segments, the common region, and the first associated ground planes are arranged on the first surface of the dielectric unit. This configuration also corresponds to a coplanar waveguide but has no first dielectric layer.

The second transmission line unit may comprise a second dielectric layer having a first surface directed away from the dielectric unit and a second surface contacting the dielectric unit. The second line segment can be arranged on one of the first and second surface of the second dielectric layer and the second associated ground plane can be arranged on the other of the first and second surface of the second dielectric layer.

As a first example, the second line segment can be arranged on the first surface of the second dielectric layer. Furthermore, the first via may extend through the second dielectric layer. This configuration corresponds to a microstrip line. In a further example, the power divider may comprise a further second dielectric layer, wherein the second dielectric layer is arranged in between the further second dielectric layer and the dielectric unit, wherein the further second dielectric layer comprises a first surface directed away from the first dielectric layer and a second surface contacting the first dielectric layer. The second transmission line may further comprise a further second associated ground plane that is arranged on the first surface of the further second dielectric layer. In addition, the plurality of second vias can extend through the further second dielectric layer. This configuration corresponds to a stripline.

In a second example, the second line segment is arranged on the second surface of the second dielectric layer, and the plurality of second vias extend through the second dielectric layer. This configuration corresponds to a reversed microstrip.

In a third example, the second line segment and the second associated ground plane arranged on the first surface of the second dielectric layer. In this example, the first via and the plurality of second vias extend through the second dielectric layer. This configuration corresponds to a coplanar waveguide.

In a fourth example, the second line segment, and the second associated ground plane are arranged on the second surface of the dielectric unit. This configuration also corresponds to a coplanar waveguide but has no second dielectric layer.

According to a second aspect, the present invention provides an antenna unit that comprises a plurality of antenna elements, such as patch antennas, and the power divider as defined above, wherein the first line segments are each connected to a respective antenna element. The antenna elements can be arranged on a same dielectric layer as the first line segments.

According to a third aspect, the present invention provides an electric device comprising the antenna unit or power divider as defined above.

Next, the invention will be described in more derail referring to the appended drawings, wherein:

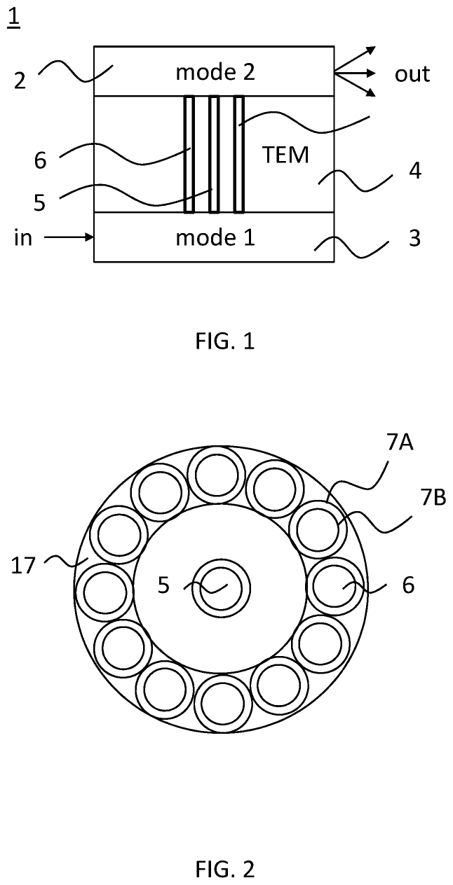

FIG. 1 illustrates a general embodiment of a power divider according to the invention in cross-sectional view;

FIG. 2 illustrates a top view of the first via and second vias used in the dielectric unit of the power divider in FIG. 1;

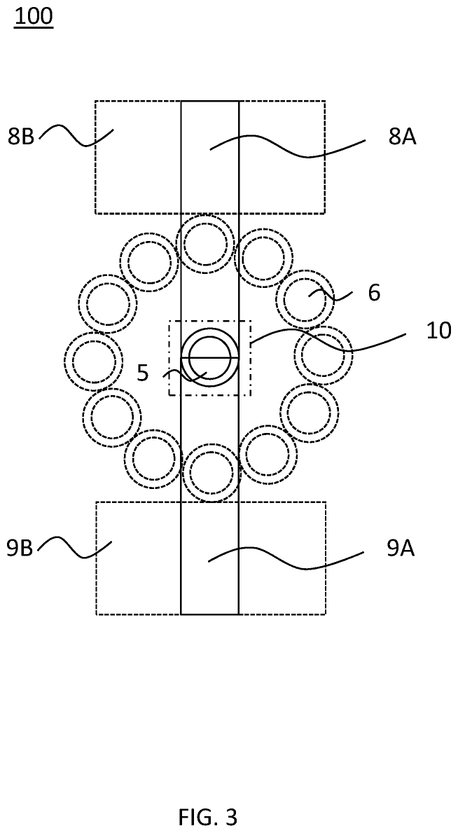

FIGS. 3, 4, and 5 illustrate a top view, a bottom view, and a cross-sectional view of a power divider similar to the power divider shown in FIG. 1, wherein the first and second transmission line units are implemented in microstrip technology;

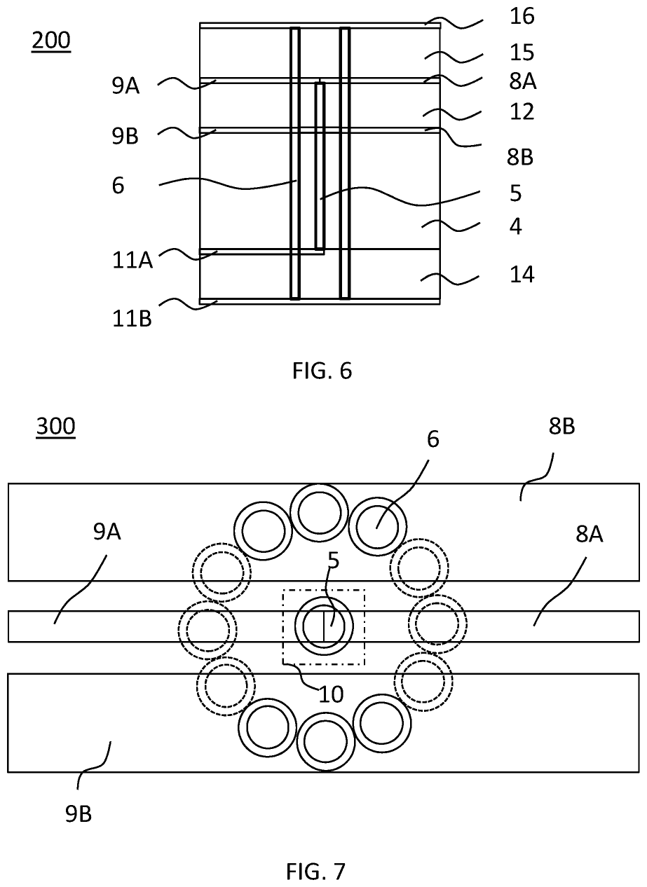

FIG. 6 illustrates a cross-sectional view of a power divider similar to the power divider shown in FIG. 1, wherein the first transmission line unit is implemented in stripline technology and the second transmission line unit in inverse microstrip technology;

FIG. 7 illustrates a top view of a power divider similar to the power divider shown in FIG. 1, wherein the first transmission line unit is implemented in coplanar waveguide technology;

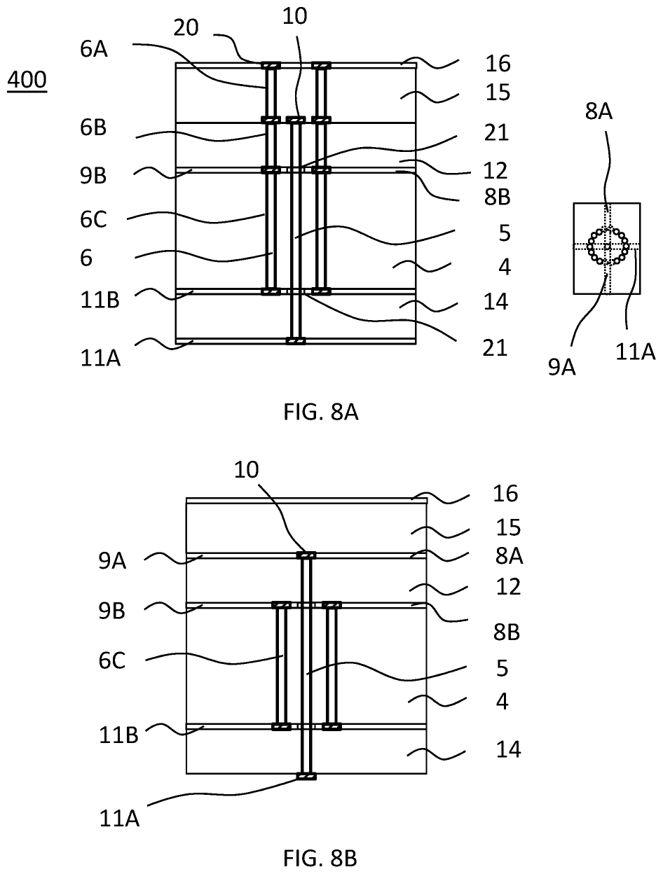

FIGS. 8A and 8B illustrate different cross-sectional views of a further power divider in accordance with the present invention of which the first transmission line unit is based on stripline technology; and

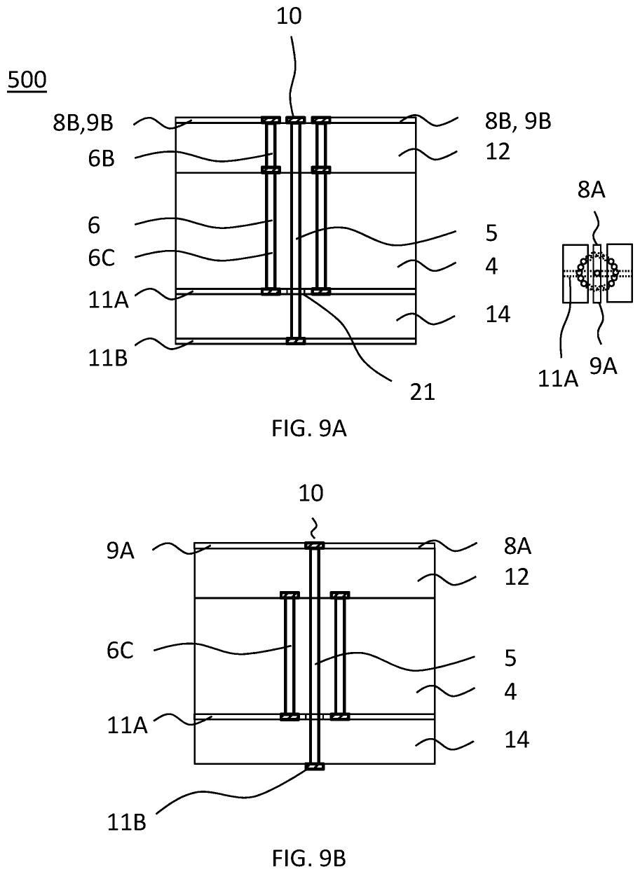

FIGS. 9A and 9B illustrate different cross-sectional views of a further power divider in accordance with the present invention of which the first transmission line unit is based on coplanar technology.

FIG. 1 illustrates a general embodiment of a power divider 1 according to the invention in cross-sectional view. In this embodiment, power divider 1 comprises a first transmission line unit 2, a second transmission line unit 3, and a dielectric unit 4 arranged between transmission line units 2, 3. Dielectric unit 4 may comprise one or more dielectric layers. Moreover, a first via 5 and a plurality of second vias 6 extend through the dielectric layer(s) of dielectric unit 4.

As shown in FIG. 2, which illustrates a top view of first via 5 and second vias 6 in dielectric unit 4, each of first via 5 and second vias 6 comprises a hole 7B which has an inner wall that is covered by metal. On the opposing ends of hole 7B, a metal pad 7A is arranged that makes electrical contact with the metal on the inner wall of hole 7B. In FIG. 2, only one of these pads is shown.

In FIG. 2, second vias 6 are electrically connected to each other by means of metal pads 7A. In situations where this is not possible, an annular ring 17 can be used to achieve the same effect. However, such ring can also be used when second vias 6 are mutually connected. The present invention does not exclude other shapes or forms as a conductive connecting element for electrically connecting second vias 6. FIG. 2 also illustrates that second vias 6 are annularly and uniformly distributed around first via 5.

First transmission line unit 2 and second transmission line unit 3 can be implemented in various kinds of technologies, such as microstrip, stripline, or coplanar waveguide. Other technologies are not excluded. The type of technology used for implementing first transmission line unit 2 can be different from the type of technology used for implementing second transmission line unit 3. Moreover, inside first transmission line unit 2 different transmission lines can be simultaneously used.

FIGS. 3-5 illustrate an implementation of a power divider 100 in accordance with power divider 1 of FIG. 1, wherein first transmission line unit 2 and second transmission line unit 3 are implemented using microstrip technology.

More in particular, power divider 100 comprises a first dielectric layer 12 and a second dielectric layer 14. On the surface of first dielectric layer 12 that is directed away from dielectric unit 4, two first line segments 8A, 9A are arranged that each extend from a common region 10. In FIG. 3, common region 10 is formed by the metal pad of first via 5. In other embodiments, dedicated patches could be used, for example a circular patch, of which a center point coincides with a center point of first via 5.

First line segments 8A, 9A cooperate, for the purpose or realizing a microstrip transmission line, with first associated ground planes 8B, 9B that are arranged on the surface of first dielectric layer 12 that is directed towards dielectric unit 4.

On the opposite side of power divider 100, a second line segment 11A is arranged on the surface of second dielectric layer 14 that is directed away from dielectric unit 4. A second associated ground plane is arranged on the surface of second dielectric layer 14 that is directed towards dielectric unit 4.

First via 5 extends from second line segment 11A through second dielectric layer 14, the dielectric layer(s) of dielectric unit 4, and first dielectric layer 12, towards common region 10. Similarly, second vias 6 extend through the dielectric layer(s) of dielectric unit 4 from second associated ground plane 11B towards first associated ground planes 8B.

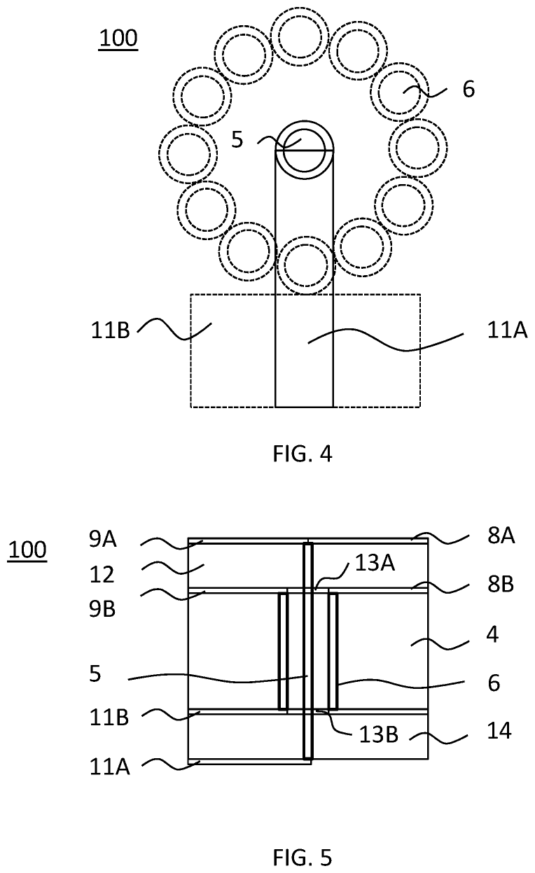

In FIGS. 3 and 4, first associated ground planes 8B and 9B and second associated ground plane 11B are shown as rectangular patches. However, the present invention is not limited thereto. For example, first associated ground planes 8B, 9B can be merged into a single first associated ground plane using ground interconnect 13A. Such a ground plane may extend to other regions that the region underneath first line segments 8A, 9A. However, it is preferred that this ground plane does not extend beyond second vias 6 to avoid the electromagnetic behavior of the coaxial transmission line like structure formed by second vias 6 and first via 5 to become adversely affected. The same holds for second associated ground plane 11B. This ground plane may even extend to other regions on the same dielectric layer that are not closely positioned to the second transmission line 11A. Similar to ground planes 8B, 9B, a ground interconnect 13B may be used.

FIGS. 6 and 7 illustrates further examples. Power divider 200 differs from power divider 100 in that first transmission line unit 2 is implemented in stripline technology and second transmission line unit 3 in inverse microstrip technology. As can be seen in FIG. 6, the stripline technology uses a further first dielectric layer 15 on which further first associated ground planes 16 are arranged. Again, ground planes 16 can be merged into a single ground plane.

When using different transmission line technologies, it may be required for first via 5 and second vias 6 to be implemented differently. For example, in FIG. 6 first via 5 extends through the dielectric layer(s) of dielectric unit 4 and through first dielectric layer 12. On the other hand, second vias 6 extend through second dielectric layer 14, the dielectric layer(s) of dielectric unit 4, first dielectric layer 12, and further first dielectric layer 15.

The routing of first line segments 8A, 9A and second line segment 11A requires a clearance through the ring of second vias 6. In this respect it is noted that first via 5 and second vias 6 may each comprise a plurality of stacked vias, each via extending through one or more dielectric layers. By leaving out one via in a stack of vias, a clearance can be created. For example, in FIG. 6, second vias 6 may each comprise a first sub-via that extends through second dielectric layer 14, a second sub-via that extends through the dielectric layer(s) of dielectric unit 4, a third sub-via that extends through first dielectric layer 12, and a fourth sub-via that extends through further first dielectric layer 15. A single stack of vias comprises a stack of a first sub-via, a second sub-via, a third sub-via and a fourth sub-via. By leaving out a third and fourth sub-via in such a stack a clearance is created allowing first line segments 8A, 9A to be routed from common region 10 to beyond second vias 6. However, the amount of clearance(s) should be minimized to prevent undesired disturbance of the TEM wave propagation in the coaxial line structure formed by the first via and the plurality of second vias.

In power divider 300 shown in FIG. 7, a coplanar waveguide technology is used for realizing first transmission line unit 2. As shown by the dashed lines, some of second vias 6 do not extend towards the surface in which first line segments 8A, 9A and ground planes 8B, 9B are arranged to avoid short-circuiting the transmission lines. Similar to the FIG. 6 embodiment, this can be achieved by leaving out parts of a second via 6 or by leaving out particular second vias 6 altogether.

FIGS. 8A and 8B illustrate two different cross-sectional views of a power divider 400 in accordance with the present invention. Power divider 400 comprises a first transmission line unit that is implemented as a stripline and a second transmission line unit that is implemented as a microstrip line.

The first transmission line unit comprises a first dielectric layer 12 and a further first dielectric layer 15. First dielectric layer 12 is in direct contact with a dielectric unit 4 that comprises one or more dielectric layers.

The first transmission line unit comprises a pair of oppositely arranged line segments 8A, 9A that are arranged in between first dielectric layer 12 and further first dielectric layer 15. First transmission line unit further comprises a first ground plane 8B, 9B that is associated with both line segments 8A, 9A, and which is arranged in between dielectric unit 4 and first dielectric layer 12. A further first ground plane 16 is provided on top of further first dielectric layer 15. Although indicated by two reference signs, i.e. 8B, 9B, it should be noted that first ground plane 8B, 9B is generally configured as a single ground plane provided with a central opening 21 as will be explained later. This single ground plane is associated with both line segments 8A, 9A. Similarly, further first ground plane 16 is also generally configured as a single plane that is associated with both line segments 8A, 9A.

The second transmission line unit comprises a second dielectric layer 14 that is covered on a side directed away from dielectric unit 4 with a second line segment 11A. In between dielectric unit 4 and second dielectric layer 14, a second ground plane 11B is provided that is configured as a single ground plane provided with an opening 21 as will be explained later.

Line segments 8A, 9A, 11A are electrically coupled using a first via 5. It should be noted that first via 5 may comprises one or more sub-vias, each sub-via extending through one or more dielectric layers.

In general, a via comprises a hole that extends through at least one dielectric layer. This hole has an inner wall that is covered with metal. Furthermore, the via is provided with a metal pad on both opposing ends of the hole. As shown in FIGS. 8A and 8B, the metal pad at the top end of first via 5 forms or at least partially overlaps with a common region from which line segments 8A, 9A extend outwardly. It should be noted that in FIGS. 8A, 8B, the width of the first and second line segments corresponds to the outer dimensions of the metal pads of first via 5. The invention is however not limited thereto, the first and second line segments may be wider or narrower than the metal pads of first via 5.

Within the context of the present invention, vias or sub-vias or combinations of them, are said to be stacked when an upper metal pad of a lower lying via or sub-via touches or at least partially overlaps with a lower metal pad of an upper lying via or sub-via.

It should be appreciated by the skilled person that any via or sub-via described in connection with the present invention and that extends through more than one dielectric layer can be replaced by a stack of vias. Similarly, a stack of multiple vias could be replaced by a single via.

Now referring to FIG. 8A, second ground plane 11B is connected to first ground plane 8B, 9B and further first ground plane 16 using a plurality of second vias. Each second via comprises a sub-via 6B that extends through first dielectric layer 12, and a sub-via 6C that extends through dielectric unit 4. Some of the second vias further comprise a sub-via 6A that extends through further first dielectric layer 15.

Sub-vias 6A, 6B, 6C are arranged in a ring pattern around first via 5. Optionally, the metal pads of sub-vias 6C can be connected to an annular metal ring. Other patterns are not excluded.

Shown separately on the right in FIG. 8A is a schematic top view of power divider 400. As shown, first line segments 8A, 9A extend perpendicular to second line segment 11A. The cross-sectional view illustrated in FIG. 8A corresponds to the view when taking the cross-section through second line segment 11A. The cross-sectional view illustrated in FIG. 8B corresponds to the view when taking the cross-section through first line segments 8A, 9A.

As shown in FIG. 8B, sub-vias 6A, 6B are omitted at specific positions. This allows first line segments 8A, 9A to extend from common region 10 to beyond the circle formed by sub-vias 6A, 6B, 6C. More in particular, sub-vias 6C are distributed uniformly and annularly around first via 5. The same holds for sub-vias 6A, 6B except at those positions where line segments 8A, 9A are arranged.

Furthermore, first ground plane 8B, 9B and second ground plane 11B are provided with a respective opening 21 through which first via 5 may extend without making electrical contact to these ground planes.

The first transmission line unit of power divider 400 is based on stripline technology. FIGS. 9A and 9B illustrate different cross-sectional views of a power divider 500 of which the first transmission line unit is based on coplanar technology. In this case, the first transmission line unit comprises a pair of opposing first line segments 8A, 9A that are arranged on first dielectric layer 12. In addition, the first transmission line unit comprises first ground planes 8B, 9B that are each arranged on both sides of the respective line segment. This is further illustrated in the schematic top view illustrated on the right in FIG. 9A. First ground planes 8B, 9B are also arranged on first dielectric layer 12.

A first via 5 connects line segments 8A, 9A and 11A. Again, a metal pad at the top end of via 5 forms or at least partially overlaps a common region 10 from which first line segments 8A, 9A extend outwardly.

Each first ground plane 8B, 9B is connected to second ground plane 11B. More in particular, both parts of each first ground plane 8B, 9B are individually connected to second ground plane 11B. This connection is made possible using a stack of a sub-via 6B that extends through first dielectric layer 12 and a sub-via 6C that extends through dielectric unit 4.

Similar to power divider 400, power divider 500 is provided with an opening 121 in second ground plane 11B.

Sub-vias 6B and 6C are arranged in a ring pattern around first via 5. Optionally, the metal pads of sub-vias 6C can be connected to an annular metal ring.

As shown in FIG. 9B, sub-vias 6B are omitted at specific positions for allowing first line segments 8A, 9A to extend outwardly from common region 10 to beyond the circle formed by sub-vias 6B and 6C. More in particular, sub-vias 6C are distributed uniformly and annularly around first via 5. The same holds for sub-vias 6B except at those positions where line segments 8A, 9A are arranged.

The present invention can easily be extended to power dividers comprising more than two first line segments. This would require omitting sub-vias 6A (if any) and sub-vias 6B at other positions as well to allow the additional first line segments to be routed away from common region 10.

In the above, the present invention has been described using detailed embodiments thereof. However, it should be noted that the invention is not limited to these embodiments but that various modifications can be made without departing from the scope of the invention which is defined by the appended claims.

In particular, aspects and/or embodiments of the present invention can also be described using the following numbered clauses:

Clause 1:

A power divider (1; 100; 200; 300), comprising:

a first transmission line unit (2) that comprises a plurality of first transmission lines, each first transmission line comprising a respective first line segment (8A, 9A) and a respective first associated ground plane (8B, 9B), wherein the first line segments extend from a single common region (10);

a second transmission line unit (3) that comprises a second transmission line, the second transmission line comprising a second line segment (11A) and a second associated ground plane (11B);

a dielectric unit (4) comprising one or more dielectric layers and having a first surface and a second surface;

a first via (5) electrically connecting the second line segment and the common region;

a plurality of second vias (6), each second via connecting the second associated ground plane to at least one of the first associated ground planes, wherein the plurality of second vias is distributed around the first via, wherein the first via and each of the second vias extend through the dielectric unit;

characterized in that

the first via is electrically isolated from the first associated ground planes and the second associated ground plane, and in that the first via and the plurality of second vias act as a coaxial transmission line having an inner conductor formed by the first via and an outer conductor formed by the plurality of second vias.

Clause 2:

The power divider according to clause 1, wherein the power divider is configured to:

convert a second electromagnetic wave of a second type that is supported by the second transmission line into a TEM wave that is supported by the plurality of second vias and the first via that act as a coaxial transmission line; and

convert said TEM wave into a first electromagnetic wave of a first type that is supported by the first transmission lines.

Clause 3:

The power divider according to clause 1 or 2, wherein the second vias are distributed uniformly and annularly around the first via.

Clause 4:

The power divider according to clause 3, wherein each of the second vias and the first via comprises:

a hole (7B) extending through at least said one or more dielectric layers between a first end and a second end and having an inner wall covered with metal;

a first metal pad (7A) formed at the first end; and

a second metal pad formed at the second end;

wherein the first and second metal pads are electrically connected through the metal covering of the inner wall.

Clause 5:

The power divider according to clause 4, wherein the second vias are arranged such that the first and/or second metal pads of adjacent second vias touch each other.

Clause 6:

The power divider according to clause 4, further comprising a first annular metal ring mutually connecting the first metal pads and/or a second annular metal ring (17) mutually connecting the second metal pads.

Clause 7:

The power divider according to any of the previous clauses, wherein the common region comprises a patch, preferably a circular patch, and preferably corresponding to the first or second metal pad as defined in any of the clauses 4-6.

Clause 8:

The power divider according to any of the previous clauses, wherein an operational frequency of the power divider lies in a range between 1 GHz and 100 GHz, and wherein a thickness of the dielectric unit is larger than 0.05 times an electrical wavelength of a TEM wave propagating through the dielectric unit at the operational frequency.

Clause 9:

The power divider according to any of the previous clauses, wherein the first transmission line unit comprises a first dielectric layer (12) having a first surface directed away from the dielectric unit and a second surface contacting the dielectric unit, wherein the first line segments and the common region are arranged on one of the first and second surface and wherein the first associated ground planes are arranged on the other of the first and second surface.

Clause 10:

The power divider according to clause 9, wherein the first line segments and the common region are arranged on the first surface of the first dielectric layer, and wherein the first via extends through the first dielectric layer.

Clause 11:

The power divider according to clause 10, the power divider further comprising:

a further first dielectric layer (15), wherein the first dielectric layer is arranged in between the further first dielectric layer and the dielectric unit, wherein the further first dielectric layer comprises a first surface directed away from the first dielectric layer and a second surface contacting the first dielectric layer;

wherein each first transmission line further comprises a respective further first associated ground plane (16) that is arranged on the first surface of the further first dielectric layer;

wherein the plurality of second vias extend through the first dielectric layer and the further first dielectric layer.

Clause 12:

The power divider according to clause 9, wherein the first line segments and the common region are arranged on the second surface of the first dielectric layer, and wherein the plurality of second vias extend through the first dielectric layer.

Clause 13:

The power divider according to clause 9, wherein the first line segments, the common region, and the first associated ground planes are arranged on the first surface of the first dielectric layer, and wherein the first via and the plurality of second vias extend through the first dielectric layer.

Clause 14:

The power divider according to any of the clauses 1-8, wherein the first line segments, the common region, and the first associated ground planes are arranged on the first surface of the dielectric unit.

Clause 15:

The power divider according to any of the previous clauses, wherein the second transmission line unit comprises a second dielectric layer (14) having a first surface directed away from the dielectric unit and a second surface contacting the dielectric unit, wherein the second line segment is arranged on one of the first and second surface of the second dielectric layer and wherein the second associated ground plane is arranged on the other of the first and second surface of the second dielectric layer.

Clause 16:

The power divider according to clause 15, wherein the second line segment is arranged on the first surface of the second dielectric layer, and wherein the first via extends through the second dielectric layer.

Clause 17:

The power divider according to clause 16, the power divider further comprising:

a further second dielectric layer, wherein the second dielectric layer is arranged in between the further second dielectric layer and the dielectric unit, wherein the further second dielectric layer comprises a first surface directed away from the second dielectric layer and a second surface contacting the second dielectric layer;

wherein the second transmission line further comprises a respective further second associated ground plane that is arranged on the first surface of the further second dielectric layer;

wherein the plurality of second vias extend through the second dielectric layer and further second dielectric layer.

Clause 18:

The power divider according to clause 15, wherein the second line segment and the common region are arranged on the second surface of the second dielectric layer, and wherein the plurality of second vias extend through the second dielectric layer.

Clause 19:

The power divider according to clause 15, wherein the second line segment and the second associated ground plane are arranged on the first surface of the second dielectric layer, and wherein the first via and the plurality of second vias extend through the second dielectric layer.

Clause 20:

The power divider according to any of the clauses 1-14, wherein the second line segment and the second associated ground plane are arranged on the second surface of the dielectric unit.

Clause 21:

An antenna unit, comprising:

a plurality of antenna elements, such as patch antennas;

the power divider as defined in any of the previous clauses, wherein the first line segments are each connected to a respective antenna element.

Clause 22:

The antenna unit according to clause 21, wherein the antenna elements are arranged on a same dielectric layer as the first line segments.

Clause 23:

An electric device comprising the antenna unit as defined in clause 21 or 22, or the power divider as defined in any of the clauses 1-20.

### LIST OF REFERENCE SIGNS

1, 100, 200, 300 Power divider
2 First transmission line unit
3 Second transmission line unit
4 Dielectric unit
5 First via
6 Second via
6A, 6B, 6C Sub-via
7A Via metal pad
7B Via Hole
8A, 9A First line segment
8B, 9B First associated ground plane
10 Common region
11A Second line segment
11B Second associated ground plane
12 First dielectric layer
13A, 13B Ground interconnect
14 Second dielectric layer
15 Further first dielectric layer
16 Further first associated ground plane
17 Annular ring
21 Opening

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. (canceled)

13. (canceled)

14. (canceled)

15. (canceled)

16. (canceled)

17. (canceled)

18. A power divider, comprising:
a dielectric unit comprising one or more dielectric layers and having a first surface and a second surface;
a first transmission line unit being of a coplanar type or a stripline type and that comprises:
a plurality of first transmission lines, each first transmission line comprising a respective first line segment and a respective first associated ground plane, wherein the first line segments extend from a single common region; and
a first dielectric layer having a first surface directed away from the dielectric unit and a second surface contacting the dielectric unit, wherein the first line segments and the common region are arranged on the first surface of the first dielectric layer;
a second transmission line unit that comprises:
a second transmission line, the second transmission line comprising a second line segment and a second associated ground plane; and
a second dielectric layer having a first surface directed away from the dielectric unit and a second surface contacting the dielectric unit, wherein the second line segment is arranged on one of the first and second surface of the second dielectric layer and wherein the second associated ground plane is arranged on the other of the first and second surface of the second dielectric layer;
a first via electrically connecting the second line segment and the common region;
a plurality of second vias distributed around the first via, wherein the first via and each of the second vias extend at least through the dielectric unit;
wherein the second vias each comprise a stack of one or more sub-vias;
wherein some of the second vias comprise a first sub-via extending through the first dielectric layer, and wherein for the other second vias, the first sub-vias are omitted thereby creating a respective clearance for each of the plurality of first line segments to allow the first line segments to be routed from the common region to beyond the second vias;
wherein the first via is electrically isolated from the first associated ground planes and the second associated ground plane, and wherein inside the dielectric unit the first via and the plurality of second vias are configured to act as a coaxial transmission line having an inner conductor formed by the first via and an outer conductor formed by the plurality of second vias,
wherein the dielectric unit has a minimum thickness configured to ensure that fringing fields associated with the conversion of electromagnetic waves at the first and second ends of the first via do not interfere with each other; and
wherein the plurality of second vias is configured for connecting the second associated ground plane to at least one of the first associated ground planes, wherein the plurality of second vias is.

19. The power divider according to claim 18, wherein an operational frequency of the power divider lies in a range between 1 GHz and 100 GHz, and wherein the thickness of the dielectric unit is larger than 0.05 times an electrical wavelength of a TEM wave propagating through the dielectric unit at the operational frequency.

20. The power divider according to claim 18, wherein the first transmission line unit is of the stripline type, the power divider further comprising a further first dielectric layer, wherein the first dielectric layer is arranged in between the further first dielectric layer and the dielectric unit, wherein the further first dielectric layer comprises a first surface directed away from the first dielectric layer and a second surface contacting the first dielectric layer, wherein each first transmission line further comprises a respective further first associated ground plane that is arranged on the first surface of the further first dielectric layer;
wherein the first associated ground planes are arranged on the second surface of the first dielectric layer; and
wherein some of the second vias further comprise second sub-vias that extend through the further first dielectric layer for electrically connecting the first associated ground planes to the further first associated ground planes and wherein for the other second vias the second sub-vias are omitted thereby creating the respective clearance for each of the plurality of first line segments to allow the first line segments to be routed from the common region to beyond the second vias.

21. The power divider according to claim 18, wherein the first transmission line unit is of the coplanar type, wherein the first associated ground planes are arranged on the first surface of the first dielectric layer.

22. The power divider according to claim 18, wherein the power divider is configured to:
convert a second electromagnetic wave of a second type that is supported by the second transmission line into a TEM wave that is supported by the plurality of second vias and the first via that act as a coaxial transmission line; and
convert said TEM wave into a first electromagnetic wave of a first type that is supported by the first transmission lines.

23. The power divider according to claim 18, wherein the second vias each comprise third sub-vias that extend through the dielectric unit and that are distributed uniformly and preferably annularly around the first via.

24. The power divider according to claim 23, wherein each of the second vias, the one or more sub-vias optionally comprised by each of the second vias, and the first via comprises:
a hole extending through one or more dielectric layers among the one or more dielectric layers of the dielectric unit, the first dielectric layer, the second dielectric layer, and, if present, the further first dielectric layer between a first end and a second end and having an inner wall covered with metal;
a first metal pad formed at the first end; and
a second metal pad formed at the second end;
wherein the first and second metal pads are electrically connected through the metal covering of the inner wall.

25. The power divider according to claim 24, wherein the second vias, or the third sub-vias thereof, are arranged such that the first and/or second metal pads of adjacent second vias or third sub-vias thereof touch each other.

26. The power divider according to claim 24, further comprising a first annular metal ring mutually connecting the first metal pads and/or a second annular metal ring mutually connecting the second metal pads.

27. The power divider according to claim 24, wherein the common region comprises a patch, preferably a circular patch, and preferably corresponding to the first or second metal pad.

28. The power divider according to claim 18, wherein the second line segment is arranged on the first surface of the second dielectric layer, and wherein the first via extends through the second dielectric layer.

29. The power divider according to claim 28, the power divider further comprising:
a further second dielectric layer, wherein the second dielectric layer is arranged in between the further second dielectric layer and the dielectric unit, wherein the further second dielectric layer comprises a first surface directed away from the second dielectric layer and a second surface contacting the second dielectric layer;
wherein the second transmission line further comprises a respective further second associated ground plane that is arranged on the first surface of the further second dielectric layer;
wherein some of the second vias comprise a fourth sub-via that extends through the second dielectric layer and a fifth sub-via that extends through further second dielectric layer and wherein for the other second vias, the fourth and fifth sub-vias are omitted thereby creating a respective clearance for the second line segment to allow the second line segment to be routed to from the first via to beyond the second vias.

30. The power divider according to claim 18, wherein the second line segment and the second associated ground plane are arranged on the first surface of the second dielectric layer, and wherein some of the second vias comprise a fourth sub-via that extends through the second dielectric layer and wherein for the other second vias, the fourth sub-vias are omitted thereby creating a respective clearance for the second line segment to allow the second line segment to be routed to from the first via to beyond the second vias.

31. An antenna unit, comprising:
a plurality of antenna elements, such as patch antennas;
the power divider as defined in claim 18, wherein the first line segments are each connected to a respective antenna element;
wherein the antenna elements are preferably arranged on a same dielectric layer as the first line segments.

32. An electric device comprising the antenna unit as defined in claim 31.

33. An electric device comprising the power divider as defined in claim 18.
